(19) United States
(12) Patent Application Publication
(10) Pub. No.: US 2008/0246499 A1
(43) Pub. Date: Oct. 9, 2008

(54) SYSTEM AND METHOD FOR THE ELECTRICAL CONTACTING OF SEMICONDUCTOR DEVICES

(75) Inventors: Markus Kollwitz, Neubiberg (DE); Sascha Nerger, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/098,029

(22) Filed: Apr. 4, 2008

(30) Foreign Application Priority Data
Apr. 5, 2007 (DE) 10 2007 016 553.8

(51) Int. Cl. G01R 31/02

(52) U.S. Cl. 324/760

(57) ABSTRACT

A device and a method for the electrical contacting of semiconductor devices. One embodiment provides for testing semiconductor devices by using a contacting device for the electrical contacting of a number of semiconductor devices to be tested and for the electrical connection with a test system. The contacting device includes a fluid container for accommodating a fluid adapted to be tempered.

### CROSS-REFERENCE TO RELATED APPLICATIONS

This Utility Patent Application claims priority to German Patent Application No. DE 10 2007 016 553.8 filed on Apr. 5, 2007, which is incorporated herein by reference.

### BACKGROUND

The following embodiments relate to the technical field of semiconductor devices, including a device and a method for electrical contacting for the testing of semiconductor devices.

In the instant context, the term semiconductor devices means in general integrated circuits or chips, respectively, as well as single semiconductors such as, for instance, analog or digital circuits or single semiconductors, as well as semiconductor memory devices such as, for instance, functional memory devices (PLAs, PALs etc.), and table memory devices (ROMs or RAMs, SRAMs or DRAMs).

For the common manufacturing of a plurality of semiconductor devices such as, for instance, integrated circuits, thin discs of monocrystalline silicon are used, which are referred to as wafers in technical language. In the course of the manufacturing process, the wafers are subject to a plurality of coating, exposure, etching, diffusion, and implantation processes, etc. so as to implement the circuits of the devices on the wafer. Subsequently, the devices implemented on the wafer may be separated from each other, for instance, by sawing, scratching, or breaking. After the processing has been finished, the semiconductor devices are individualized in that the wafer is sawn apart, or scratched and broken, so that the individual semiconductor devices are then available for further processing.

After performing the above-mentioned wafer processing, the devices implemented on the wafer may, for instance, be tested in wafer tests by using appropriate test devices. After the sawing apart or the scratching and breaking, respectively, of the wafer, the chips that are then available individually are molded in a plastics mass, wherein the semiconductor devices obtain specific packages such as, for instance, TSOP or FBGA packages, etc. The devices are equipped with contact faces in the form of contact pads by which the circuits of the semiconductor device can be contacted electrically. During the molding of the chips in the plastics mass, these contact faces or contact pads are connected with external connection pins or contact balls via bonding wires (bonding).

As mentioned above, semiconductor devices are, for examining their functions, usually subject to comprehensive tests in the course of the manufacturing process in the semi-finished and/or finished state even prior to being molded or incorporated in semiconductor modules. By using appropriate test systems or test cells, it is also possible to perform test methods on waver level even prior to the individualization of the semiconductor devices so as to be able to examine the operability of the individual semiconductor devices still on the wafer prior to their further processing.

The present invention serves in one embodiment for the use during the testing of the operability of semiconductor devices on wafer level with appropriate test systems or test devices. In order to electrically connect the semiconductor device to be tested on a wafer in a test station with the test system, a specific contacting device, namely a semiconductor device test card or a needle card which is also referred to as probe card by the expert is usually used. Needle-shaped contact tips or contact needles are provided at the probe card which contact the contact faces or contact pads of the semiconductor devices to be tested.

By using the probe card it is possible to generate, at a test station, the signals required for the testing of semiconductor devices that are available on the wafer by using the test device connected with the probe card, and to introduce them into the respective contact pads of the semiconductor devices by using the contact needles provided at the probe card. The signals output by the semiconductor device at contact pads in reaction to the input test signals are in turn tapped by the needle-shaped connections of the probe card and, for instance, transferred to the test device via a signal line connecting the probe card with the test device, where an evaluation of the signals may take place.

During the testing on wafer level, the chip-internal voltages are, for instance, impressed from outside via current supply channels by the probe card of a test system and further via supply voltage contact points on the chip. Via the contact needles of the probe card, the output voltage and signals generated by the semiconductor device are also tapped at the contact pads of the semiconductor device and transmitted to the test system or the tester, respectively, so as to examine the operability of the semiconductor device. It is also possible to examine semiconductor devices on wafer lever for their operability under extreme stress conditions such as, for instance, in a waver-level-burn-in method with increased temperature. During the heating of the semiconductor device on the wafer, the probe card is also heated. This may lead to thermal tensions and drifting of the probe card, which may impair the contacting between the probe card and the semiconductor device to be tested.

The electrical voltage applied at an external contact point of the semiconductor device on the wafer may, due to contact interferences between the probe card or the contact needle of the test system and the external contact face of the semiconductor device, be distinctly smaller than the supply voltage delivered by the test system. This may result in that the semiconductor device or at least particular switching blocks of the semiconductor device would not be stressed sufficiently during a test method under stress conditions. If no contact is established between the contact needle of the test system and the external contact point of the memory device, neither a voltage can be applied nor be detected reliably via the contacting, which would result in a falsification of the test result.

During the testing of semiconductor devices on wafer level, the wafers are arranged on wafer carriers that are also referred to as “chucks” in technical language. For transporting and positioning of the wafers in the test stations, they are retained on the wafer carrier by using negative pressure. The wafer carriers are introduced with the wafers arranged thereon in the test station or test device, which are also referred to as “probers” in technical language. In the test device, the wafer carriers with the wafers attached thereon are heated to the desired stress temperature or target temperature, and the semiconductor devices on the wafer are contacted via the contact needles of the probe card so as to perform one or a plurality of test methods subsequently.

For the testing of larger semiconductor devices with a plurality of contact pads, lager probe cards with a larger number of contact needles, “large scale probe cards”, are also used. During the heating of such “large scale probe cards” to the target temperature (e.g., 88° C.), the probe card may, due to the thermally conditioned expansion, for instance, bend in a spatial direction (e.g., the z-direction), and move in other spatial directions (e.g., in x- and y-direction). These thermally conditioned movements may also occur a long time after the wafer carrier has reached the target temperature in the test device.

In the previously known test devices, the temperature increase is achieved by an appropriate heating of a heatable wafer carrier, so that the wafer arranged on the wafer carrier and the semiconductor devices or chips available thereon are heated successively. The heating of the probe card is performed predominantly via the temperature bridge by the contact of the contact needles with the semiconductor devices to be tested. This temperature bridge, however, allows for a relatively small heat transfer from the heated wafer carrier through the contacted semiconductor devices and through the thin needles only, so that the probe card reaches the target temperature and a thermal stability after a longer time only. In some production or test processes, durations in the range of hours are therefore sometimes scheduled until the probe card has stabilized thermally, which results in a high test time or a low throughput.

When the wafer is changed, the probe card and the test head as a rule remain unchanged in their positions while the chuck that carries, sucks, and heats the wafer (and thus also heats the probe card) is removed from the probe card for loading the new wafer, and is therefore no longer capable of heating it. In so doing, the probe card cools down relatively quickly, so that a temperature difference between the probe card and the semiconductor devices that have been newly loaded in the test device will occur. This temperature difference causes thermal tensions and contacting problems which decrease only with a time-intensive adaptation of the temperature between the probe card and the semiconductor devices to be tested.

“Retention tests” in which the lifetime of a semiconductor device is tested have a better test coverage due to the longer test phases, wherein the probe card may again become instable by the drifting in x-, y- or z-direction. The latter may result in a poor contact of the contact needles (“probe pins”), which may finally result in the discarding of the tested chip. This effect illustrates in one embodiment “post fuse tests” in which chips that have been repaired by using fusing are tested with less test time per contacting of the probe card (“touchdown”).

The known test devices therefore have the disadvantages of a poor electrical contacting of the semiconductor devices or chips to be tested on the wafer, and a loss of yield related therewith. Furthermore, it is not always possible to observe a particular test accuracy, and the waiting time caused by the heating time of the probe card causes a minor throughput per test system and thus higher test costs.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate similar parts.

FIG. 1 illustrates a schematic representation of a device according to one embodiment.

FIG. 2 illustrates a schematic representation of a device according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments avoid the temperature drift with probe cards during the testing of semiconductor devices on wafer level, and thus to avoid an irregular contact between the contact tips of the probe card and the contact pads of the semiconductor devices to be tested.

In accordance with one embodiment a device for the electrical contacting of a number of semiconductor devices to be tested and for the electrical connection with a test system in which a fluid container is provided for accommodating a fluid adapted to be tempered. The fluid container may be designed such that the fluid contained therein at least partially surrounds and thus tempers the semiconductor devices to be tested and/or components of the device. By the direct contact between the tempered fluid and the semiconductor devices and/or components of the contacting device, they are taken to the temperature of the fluid within short time.

By increasing the thermal contact between the tempered fluid and the semiconductor devices to be tested and the components of the contacting device it is possible to quickly take them to a desired target temperature. Furthermore, the thermal stability of the semiconductor devices to be tested, the probe card, and the contact needles of the contacting device will be reached within shorter time.

The heating time of the semiconductor devices to be tested and of the probe card shortens considerably, which enables a higher throughput of the test system. Since the test system cannot be used during the heating time, the present embodiments may contribute to higher test rates and lower test costs.

For implementation of one embodiment, the tester chamber or “prober chamber” in which the semiconductor devices to be tested are available may be filled at least partially with the tempered fluid, so that the semiconductor devices to be tested, the wafer, the contact needles, and/or the probe card of the contacting device at least partially get into contact with the tempered fluid. By this direct contact with the tempered fluid, the semiconductor devices to be tested, the contact needles, and the probe card of the contacting device assume the temperature of the fluid within short time.

By the surrounding of the probe card with the tempered fluid, the temperature distribution of the probe card becomes more homogeneous. The probe card also remains thermally more stable since the change of a tested wafer or the stepping from one contacting of the probe card to the next one has less influence on the temperature of the probe card due to the higher heat capacity of the surrounding fluid. Thus, it is possible to achieve better contacts, higher yield, and better testing accuracy.

The tester chamber in which the semiconductor devices to be tested, the contact needles, and the probe card are available may, for instance, be completely filled with a thermally well conductive, but electrically poorly conductive fluid. This way, the semiconductor devices to be tested, the contact needles, and the probe card are almost completely surrounded by the tempered fluid. Thus, it is possible to achieve better temperature stability of the probe card.

Instead of the previous transfer of heat only via the contact needles on the probe card, it is possible with the present invention to heat the probe card directly and from all sides by surrounding it with a tempered fluid. The present invention can, however, also be used for performing function tests with semiconductor devices under low temperatures. For adjusting a high temperature, a correspondingly heated fluid may be used, and for adjusting a low temperature, a correspondingly cooled liquid, e.g., a cooled fluid, a gas, a liquid gas, or vapor may be used.

To temper the semiconductor devices to be tested to a desired target temperature, the fluid container may be designed such that the fluid contained therein at least partially surrounds a number of semiconductor devices to be tested. As described above, a number of contact needles that are arranged at a probe card may be provided for contacting the semiconductor devices to be tested. The fluid container may be designed such that the fluid contained therein at least partially surrounds the contact needles. Furthermore, the fluid container may be designed such that the fluid contained therein also surrounds the probe card at least partially.

Since the semiconductor devices to be tested are arranged on a wafer during testing on wafer level, the fluid container may also be designed such that the fluid contained therein at least partially surrounds the wafer and the semiconductor devices arranged thereon. Usually, the wafers are arranged on wafer carriers (“chucks”) in the test stations. The fluid container may therefore also be designed such that the fluid contained therein surrounds the wafer carrier at least partially.

As already mentioned, the fluid may be a gas or a liquid including a good thermal conductivity so as to achieve a thermal coupling between the fluid and the objects contacted or surrounded by the fluid which is as good as possible. Furthermore, the fluid should have an electrical conductivity that is as low as possible so as to avoid undesired electrical currents or even short circuits, for instance, between contact faces of the semiconductor devices to be tested.

The tempering of the above-mentioned components by thermal contact to the fluid is, for instance, performed by the arrangement of the components in the interior of the fluid container. In one embodiment, it is, however, also conceivable to merely provide flow means by which the tempered fluid from a fluid container is directed on the semiconductor devices to be tested and/or components of the device so as to bring the semiconductor devices to be tested and/or components of the device in thermal contact with the fluid and thus to a desired temperature. Such means might, for instance, be correspondingly oriented nozzles or fans.

In an arrangement with the object of arranging the semiconductor devices to be tested and/or components of the test device in the interior of the fluid container, it may be of advantage to provide means for adjusting the position of the fluid container so that it can be positioned in a desired position on the desired level in the test device.

Devices for adjusting the fill level of the fluid in the fluid container may be provided. Heating devices may be provided by which the fluid can be tempered to a predetermined target temperature. Coolants may be provided by which the fluid can be tempered to a predetermined target temperature. Devices for circulating the fluid in the fluid container may be provided, so that the fluid is kept in permanent movement in the fluid container and a homogeneous temperature distribution is thus maintained. Devices for measuring the temperature of the fluid in the fluid container may be provided so as to check and control the temperature of the fluid.

Additionally, devices for generating heat rays such as, for instance, radiant heaters may be provided so as to heat the semiconductor devices to be tested, the wafer, the contact needles, the probe card, and/or the wafer carrier. In the fluid container, a combination of a sensor, heating means, and a propeller, for instance, may arrange for checking the temperature of the fluid, additional heating power, and a better distribution of the tempered fluid so as to take the probe card, the contact needles, the wafer, and/or the semiconductor devices to be tested to the desired temperature or maintain them on the desired temperature, respectively.

By the applying of radiant heaters in the prober area, there is a relatively homogeneous temperature distribution in the relevant test system in which both the probe card and the wafer are positioned. This way, it is possible to substantially reduce the heating-up time, so that an additional heating power can be released. Furthermore, the temperature distribution can form in a more homogeneous and stable manner in the probe card. Also the coupling of a (“cold”) probe card that has been newly introduced in this region to the temperature balance may be increased by the existence of a thermally conductive gas, vapor, or liquid.

One embodiment provides a method for testing semiconductor devices by using a contacting device for the electrical contacting of a number of semiconductor devices to be tested and for the electrical connection with a test system, wherein the contacting device includes a fluid container for accommodating a fluid adapted to be tempered. The method includes:

tempering the fluid in the fluid container;

tempering semiconductor devices to be tested by using heat exchange with the fluid;

contacting a number of semiconductor devices to be tested by using the contacting device; and

performing one or a plurality of tests.

In the method according to one embodiment, tempering may mean both the heating and the cooling down to a desired target temperature. In so doing, at least parts of the contact using the contacting device may be tempered, i.e. heated or cooled down, by heat exchange with the fluid. The contact needles of the contacting device may be tempered by heat exchange with the fluid. The probe card of the contacting device may be tempered by heat exchange with the fluid. The wafer on which the semiconductor devices to be tested are arranged may be tempered by heat exchange with the fluid. The wafer carrier on which the wafer is arranged may be tempered by heat exchange with the fluid.

The tempering of the semiconductor devices to be tested, of the wafer, the contact needles, the probe card, and/or the wafer carrier may be performed by using heat exchange with the fluid in that the semiconductor devices to be tested, the wafer, the contact needles, the probe card, and/or the wafer carrier are at least partially introduced into the fluid container containing the tempered fluid. In one embodiment, in the method according to one embodiment, a tempered fluid flow may be directed on the semiconductor devices to be tested and/or components of the device so as to bring the semiconductor devices to be tested and/or components of the device in thermal contact with the fluid and thus to a desired temperature.

In the method according to one embodiment, the fluid may be tempered to a temperature in the range of a particular target temperature. For instance, with a desired heating to a particular target temperature, the fluid may also be heated somewhat beyond the target temperature so as to correspondingly accelerate the tempering of the semiconductor devices to be tested and/or of components of the test device.

In accordance with the method according to one embodiment it may be provided that the test procedures are performed while the semiconductor devices to be tested, the wafer, the contact needles, the probe card, and/or the wafer carrier are at least partially positioned in the fluid container containing the tempered fluid. It may also be provided that the test procedures are only performed at the semiconductor devices once the semiconductor devices to be tested, the wafer, the contact needles, the probe card, and/or the wafer carrier have been tempered to a desired temperature. Furthermore, it may be provided that the test procedures are only performed once the semiconductor devices to be tested, the wafer, the contact needles, the probe card, and/or the wafer carrier have reached a thermally stable state.

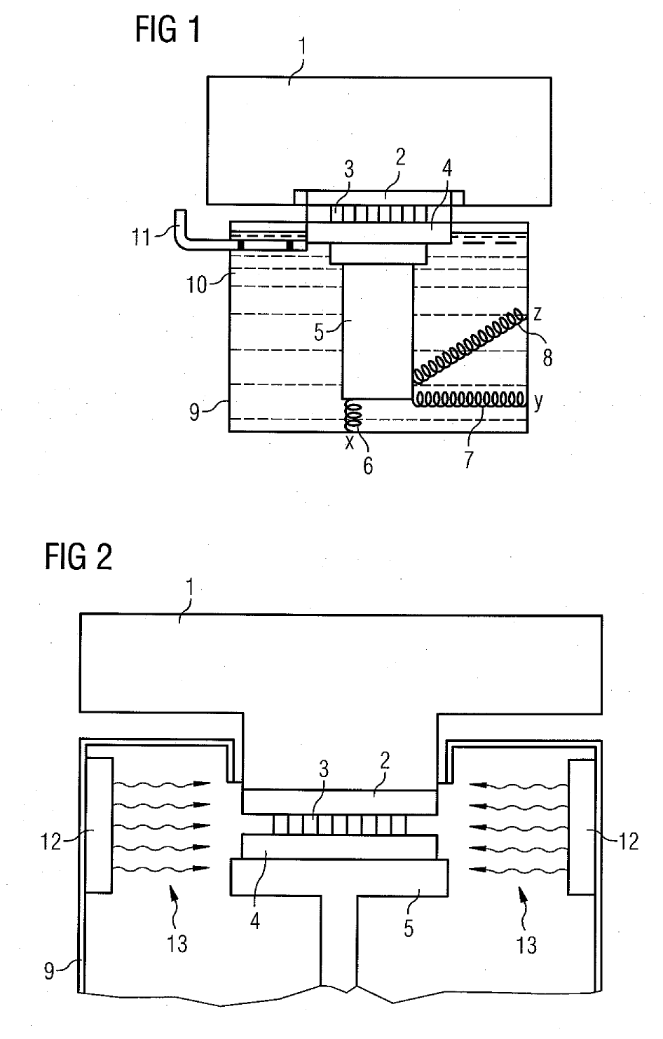

FIG. 1 illustrates a schematic representation of a device for testing semiconductor device and for the electrical connection of the semiconductor devices with a test system in accordance with one embodiment. The test device includes a test head 1, at the bottom of which a probe card 2 is arranged. At the bottom of the probe card 2, a number of contact needles 3 are provided, the contact needles 3 contacting contact faces of semiconductor devices to be tested so as to electrically connect them with a test system (not illustrated).

The test situation illustrated in FIG. 1 is a function test on wafer level, i.e. the semiconductor devices to be tested are still available on a wafer 4. Thus, the semiconductor devices are contacted by the probe card 2 via the contact needles 3 directly on the wafer 4 that has been introduced in the test device before. To this end, the wafer 4 is arranged on a wafer carrier 5 (“chuck”) and is, for instance, fixed by a negative pressure mechanism. To bring the wafer 4 and the semiconductor devices positioned thereon in the correct position relative to the probe card 3 and the contact needles 4, the wafer carrier 5 is adapted to be shifted in all three spatial directions x, y, and z via micrometer adaptation mechanisms 6, 7, and 8.

In one embodiment as illustrated in FIG. 1, a fluid container 9 is provided which is filled with a fluid 10 adapted to be tempered and surrounding the lower portion of the test device. The fluid container 9 is designed such that the semiconductor devices to be tested, the wafer 4, the contact needles 3, and the probe card 2 are at least partially positioned in the fluid container 9 containing the tempered fluid 10, and the wafer carrier 5 is completely positioned therein.

This way, the tester chamber or “prober chamber” in which the semiconductor devices to be tested are positioned is filled at least partially with the tempered fluid 10. Thus, the semiconductor devices to be tested, the wafer 4, the contact needles 3, the probe card 2, and the wafer carrier 5 are at least partially in thermal contact with the tempered fluid 10. By this thermal coupling it is possible to reduce the time required for the tempering of the semiconductor devices to be tested and/or the components 2, 3, 4, 5 of the test device mentioned.

In the fluid container 9, a combination 11 of a sensor, heating loops, and propellers is arranged. By using the heating loops it is possible to generate a heating power in the interior of the fluid container 9 so as to temper the fluid 10. By using the propeller(s), a better distribution of the tempered fluid 10 may be achieved so as to take the components 2, 3, 4, 5 of the test device mentioned and/or the semiconductor devices to be tested to the desired temperature or to maintain them on the desired temperature, respectively.

By the sensor in the interior of the fluid container 9 it is possible to check and control the temperature of the fluid 10. To this end, the sensor is adapted to generate, as a function of the temperature of the fluid 10, electrical signals that are transmitted to an electronic control (not illustrated) that controls the operation of the heating means.

FIG. 2 illustrates a schematic representation of a device according to a further embodiment. The structure of this embodiment substantially equals the structure of the embodiment illustrated in FIG. 1, so that the description is referred to. In the embodiment illustrated in FIG. 2, radiant heaters 12 are additionally provided in the interior of the fluid container 9 which generate heat rays 13. The radiant heaters 12 are arranged and oriented such that the heat rays 13 hit the probe card 2, the contact needles 3, and the wafer 4 with the semiconductor devices to be tested, and thus heat same. The interior of the fluid container 9 may again be filled with a tempered fluid that ensures a good thermal coupling.

By the applying of radiant heaters 12 in the prober region of the test device there is a relatively homogeneous temperature distribution in the region in which both the probe card 2 with the contact needles 3 and the wafer 4 with the semiconductor devices to be tested are positioned. By the additional heating power, the heating time of the semiconductor devices to be tested and of the relevant components 2, 3, 4, 5 of the test device can be further reduced. Furthermore, the temperature distribution in the probe card may form in a more homogeneous and stable manner. The coupling of a (“cold”) probe card 2 that has been newly incorporated in this region to the temperature balance may also be increased by the presence of a thermally conductive gas, vapor, or liquid in the prober region of the test device.

One embodiment also relates to a test system for testing semiconductor devices. The test system includes control electronics for controlling the sequence of operations of the test system, at least one input device for inputting measurement values, and at least one output device for outputting test results. The input device and the output device are each coupled to the control electronics. The input device includes at least one contacting device that contacts the semiconductor device to be tested and includes a fluid container 9 for accommodating a fluid 10 adapted to be tempered. The test system is designed such that it is capable of performing the method as described above.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system comprising:
a device for the electrical contacting of a number of semiconductor devices to be tested and for the electrical connection with a test system, including a fluid container configured for accommodating a fluid adapted to be tempered.

2. The system of claim 1, comprising wherein the fluid container is configured such that the fluid contained therein at least partially surrounds and thus tempers components of the device.

3. The system of claim 1, comprising wherein, for contacting the semiconductor devices to be tested, a number of contact needles is provided and the fluid container is designed such that the fluid contained therein at least partially surrounds the contact needles.

4. The system of claim 3, comprising wherein the contact needles are arranged at a probe card, and wherein the fluid container is designed such that the fluid contained therein at least partially surrounds the probe card.

5. The system of claim 1, comprising wherein the fluid container is designed such that the fluid contained therein at least partially surrounds a number of semiconductor devices to be tested.

6. The system of claim 1, comprising wherein the semiconductor devices to be tested are arranged on a wafer, and wherein the fluid container is designed such that the fluid contained therein at least partially surrounds the wafer and the semiconductor devices arranged thereon.

7. The system of claim 1, comprising wherein the wafer is arranged on a wafer carrier, and wherein the fluid container is designed such that the fluid contained therein at least partially surrounds the wafer carrier.

8. The system of claim 1, comprising wherein heating devices are provided by which the fluid can be tempered to a predetermined target temperature.

9. The system of claim 1, comprising wherein coolants are provided by which the fluid can be tempered to a predetermined target temperature.

10. The system of claim 1, comprising wherein devices for circulating the fluid in the fluid container are provided.

11. The system of claim 1, comprising wherein devices for measuring the temperature of the fluid in the fluid container are provided.

12. The system of claim 1, comprising wherein the fluid is a gas, a liquid, or vapor.

13. The system of claim 1, comprising wherein devices for generating heat rays are provided so as to heat the semiconductor devices to be tested, the wafer, the contact needles, the probe card, and/or the wafer carrier.

14. The system of claim 1, comprising wherein devices are provided for adjusting the fill state of the fluid in the fluid container.

15. The system of claim 1, comprising wherein devices are provided for adjusting the position of the fluid container.

16. The system of claim 1, comprising wherein flow devices are provided by which the tempered fluid is directed on the semiconductor devices to be tested and/or the components of the device.

17. A method for testing semiconductor devices comprising:
using a contacting device for the electrical contacting of a number of semiconductor devices to be tested and for the electrical connection with a test system, wherein the contacting device comprises a fluid container for accommodating a fluid adapted to be tempered;
tempering the fluid in the fluid container;
tempering semiconductor devices to be tested by heat exchange with the fluid;
contacting a number of semiconductor devices to be tested by using the contacting device; and
performing one or a plurality of tests.

18. The method of claim 17, further comprising:
tempering at least parts of the contacting device by heat exchange with the fluid.

19. The method of claim 17, further comprising:
tempering contact needles of the contacting device by heat exchange with the fluid.

20. The method of claim 17, further comprising:
tempering a probe card of the contacting device by heat exchange with the fluid.

21. The method of claim 17, further comprising:
tempering a wafer on which the semiconductor devices are arranged by heat exchange with the fluid.

22. The method of claim 21, further comprising:
tempering a wafer carrier on which the wafer is arranged by heat exchange with the fluid.

23. The method of claim 17, comprising performing the tempering in that the contacting device is at least partially introduced in the fluid container containing the tempered fluid.

24. The method of claim 22, comprising directing a fluid flow on the semiconductor devices to be tested, the wafer, the contact needles, the probe card, and/or the wafer carrier so as to establish a thermal contact with the fluid.

25. A test system for testing semiconductor devices comprising:
control electronics;
at least one input device for inputting measurement values; and at least one output device for outputting test results,
wherein the input device and the output device are coupled with the control electronics and the input device comprises at least one contacting device of claim 1 which contacts the semiconductor devices to be tested.
